(19) United States
(12) Patent Application Publication
(10) Pub. No.: US 2024/0222380 A1
(43) Pub. Date: Jul. 4, 2024

(54) THIN FILM TRANSISTOR SUBSTRATE AND METHOD OF MANUFACTURING THE SAME AND DISPLAY APPARATUS USING THE SAME

(71) Applicant: LG DISPLAY CO., LTD., SEOUL (KR)

(72) Inventors: JuHeyuck BAECK, Gyeonggi-do (KR); Dohyung LEE, Gyeonggi-do (KR)

(73) Assignee: LG DISPLAY CO., LTD., SEOUL (KR)

(21) Appl. No.: 18/384,766

(22) Filed: Oct. 27, 2023

(30) Foreign Application Priority Data
Dec. 30, 2022 (KR) 10-2022-0190786

(51) Int. Cl. H01L 27/12

(52) U.S. Cl. CPC H01L 27/1225; H01L 27/127; H10K 59/1213

(57) ABSTRACT

A thin film transistor substrate includes a substrate; and a gate electrode and an active layer spaced up and down on the substrate, wherein the active layer includes a first active layer and a second active layer, the first active layer is disposed closer to the gate electrode than the second active layer, a gate insulating film is additionally disposed between the first active layer and the gate electrode, the first active layer and the gate insulating film are in contact with each other, and, the first active layer includes a crystalline oxide semiconductor material, and the second active layer includes an amorphous oxide semiconductor material.

### CROSS-REFERENCE TO RELATED APPLICATION

This application claims the priority of Korean Patent Application No. 10-2022-0190786 filed on Dec. 30, 2022, which is hereby incorporated by reference in its entirety.

### BACKGROUND

### Field of the Disclosure

The present disclosure relates to a thin film transistor substrate, a manufacturing method thereof, and a display apparatus using the same.

### Description of the Background

Since a thin film transistor may be manufactured on a glass substrate or a plastic substrate, it is widely used as a switching element or a driving element, etc. of a display apparatus such as a liquid crystal display apparatus or an organic light emitting display device, etc.

The thin film transistor may be divided into an amorphous silicon thin film transistor using amorphous silicon as an active layer, a polycrystalline silicon thin film transistor using polycrystalline silicon as an active layer, an oxide semiconductor thin film transistor using an oxide semiconductor as an active layer and another semiconductor thin film transistor using another semiconductor, such as compound semiconductor, as an active layer.

Among them, the oxide semiconductor thin film transistor (Oxide semiconductor TFT) has the advantage of being able to easily obtain the desired physical properties because it has high mobility and may have a large electrical resistance change depending on the oxygen content. In addition, the manufacturing cost is low because the oxide constituting the active layer may be formed at a relatively low temperature during the manufacturing process of the oxide semiconductor thin film transistor. Due to the nature of the oxide, since the oxide semiconductor is transparent, it is also advantageous to implement a transparent display apparatus.

Recently, to reduce the delay of the signal, a thin film transistor is manufactured using an oxide semiconductor having high mobility. In general, in the case of a thin film transistor with high mobility, the threshold voltage Vth may shift in a negative (−) direction.

If the threshold voltage Vth is shifted in the negative (−) direction, leakage current may occur, and leakage current may cause a defect in the initial image or increase the panel's power consumption due to leakage current.

To prevent such a leakage current problem, a method has been proposed to shift the threshold voltage in a positive direction by increasing the oxygen content in the active layer or increasing the oxygen content in the gate insulating film, however, in this case, there is a problem that the active layer of the thin film transistor is easily degraded due to the excess oxygen contained in the active layer or the gate insulating film, reducing the reliability of the thin film transistor.

Therefore, a high-mobility oxide thin film transistor that does not degrade the reliability of the thin film transistor even if the process of securing the threshold voltage Vth of the thin film transistor in the positive (+) direction is carried out, is required.

The description provided in the background section should not be assumed to be prior art merely because it is mentioned in or associated with the background section. The background section may include information that describes one or more aspects of the subject technology.

### SUMMARY

Accordingly, the present disclosure is directed to a thin film transistor substrate, a manufacturing method thereof, and a display apparatus using the same that substantially obviate one or more of problems due to limitations and disadvantages described above.

More specifically, the present disclosure is to provide thin film transistor substrate that does not degrade reliability even if the process of securing the threshold voltage (Vth) in the positive (+) direction is carried out in a thin film transistor equipped with a high mobility oxide semiconductor and a display apparatus comprising the same.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a thin film transistor substrate includes a substrate; and a gate electrode and an active layer spaced up and down on the substrate, wherein the active layer includes a first active layer and a second active layer, the first active layer is disposed closer to the gate electrode than the second active layer, a gate insulating film is additionally disposed between the first active layer and the gate electrode, the first active layer and the gate insulating film are in contact with each other, and, the first active layer includes a crystalline oxide semiconductor material, and the second active layer includes an amorphous oxide semiconductor material, a method of manufacturing the same and a display apparatus comprising the same.

In another aspect of the present disclosure, a thin film transistor substrate includes a substrate; and a gate electrode and an active layer spaced up and down on the substrate, wherein the active layer includes a first active layer, a second active layer and a third active layer, the first active layer and the third active layer includes a crystalline oxide semiconductor material, and the second active layer includes an amorphous oxide semiconductor material, a method of manufacturing the same and a display apparatus comprising the same.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a plan view of a thin film transistor substrate according to an exemplary aspect of the present disclosure.

FIG. 2A is a cross-sectional view of a thin film transistor substrate according to an exemplary aspect of the present disclosure.

FIG. 2B is a cross-sectional view of a thin film transistor substrate according to another exemplary aspect of the present disclosure.

FIG. 3 is a cross-sectional view of a thin film transistor substrate according to another exemplary aspect of the present disclosure.

FIG. 4A is a cross-sectional view of a thin film transistor substrate according to another exemplary aspect of the present disclosure.

FIG. 4B is a cross-sectional view of a thin film transistor substrate according to another exemplary aspect of the present disclosure.

FIG. 5 is a cross-sectional view of a thin film transistor substrate according to another exemplary aspect of the present disclosure.

FIG. 6 is a cross-sectional view of a thin film transistor substrate according to another exemplary aspect of the present disclosure.

FIG. 7A is a transmission electron microscope (TEM) photograph of an active layer provided in a thin film transistor substrate in accordance with an exemplary aspect of present disclosure.

FIG. 7B is a schematic diagram showing an atomic model of an active layer included in a thin film transistor substrate according to another exemplary aspect of the present disclosure, and a schematic diagram showing an atomic model of the first active layer or the third active layer of FIG. 6A.

FIG. 8 is a graph illustrating energy levels for each layer of a thin film transistor according to an exemplary aspect of the present disclosure.

FIG. 9A is a V_{GS}-I_{DS} graph of a thin film transistor substrate according to another exemplary aspect of the present disclosure.

FIG. 9B is a V_{GS}-I_{ds} graph of a thin film transistor substrate according to a comparative example.

FIG. 10 is a PBTS (Positive Bias Temperature Stress) test graph for thin film transistor substrates according to an exemplary aspect of present disclosure and comparative example.

FIG. 11 is a cross-sectional view of a display apparatus including a thin film transistor substrate according to another exemplary aspect of the present disclosure.

FIG. 12 is a schematic diagram of a display apparatus according to an exemplary aspect of the present disclosure.

FIG. 13 is a circuit diagram of a shift register according to an exemplary aspect of the present disclosure.

FIG. 14 is a circuit diagram of one pixel provided in a display apparatus according to an exemplary aspect of the present disclosure.

FIG. 15 is a circuit diagram of one pixel provided in a display apparatus according to another exemplary aspect of the present disclosure.

FIG. 16 is a circuit diagram of one pixel provided in a display apparatus according to another exemplary aspect of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to aspects of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof will be clarified through the following aspects, described with reference to the accompanying drawings. The present disclosure may, however, be embodied in different forms and should not be construed as being limited to the aspects set forth herein. Rather, these aspects are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing aspects of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof. Any implementation described herein as an “example” is not necessarily to be construed as preferred or advantageous over other implementations.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

The terms, such as “below,” “lower,” “above,” “upper” and the like, may be used herein to describe a relationship between element(s) as illustrated in the drawings. It will be understood that the terms are spatially relative and based on the orientation depicted in the drawings.

It will be understood that, although the terms “first,” “second,” “(a),” and “(b),” etc. may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various aspects of the present disclosure may be partially or overall coupled to or combined with each other, and may be variously inter-operated with each other and driven technically The aspects of the present disclosure may be carried out independently from each other, or may be carried out together in a co-dependent relationship.

Unless otherwise defined, all terms (including technical and scientific terms) used herein have the same meaning as commonly understood by one of ordinary skill in the art to which example aspects belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

In the drawings, the same or similar elements are denoted by the same reference numerals even though they are depicted in different drawings.

In the aspects of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one aspect of the present disclosure may be the drain electrode in another exemplary aspect of the present disclosure, and the drain electrode in any one aspect of the present disclosure may be the source electrode in another exemplary aspect of the present disclosure.

In one or more aspects of the present disclosure, for convenience of explanation, a source region is distinguished from a source electrode, and a drain region is distinguished from a drain electrode. However, aspects of the present disclosure are not limited to this structure. For example, a source region may be a source electrode, and a drain region may be a drain electrode. Also, a source region may be a drain electrode, and a drain region may be a source electrode.

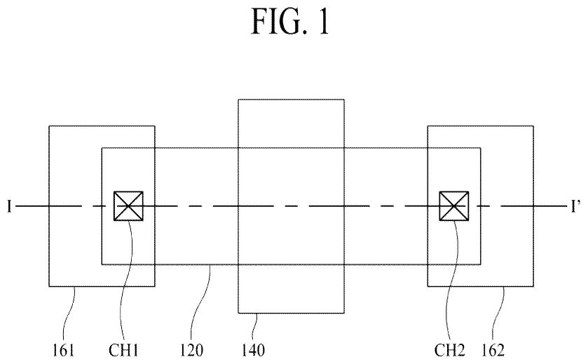

FIG. 1 is a plan view of a thin film transistor substrate according to an exemplary aspect of the present disclosure.

As shown in FIG. 1, the thin film transistor according to an exemplary aspect of present disclosure includes an active layer 120, a gate electrode 140, a source electrode 161, and a drain electrode 162.

The active layer 120 may extend in the first direction, for example, in a horizontal direction, and may be electrically connected to the source electrode 161 on one side, for example, the left side of the active layer 120, and may be electrically connected to the drain electrode 162 on another side, for example, on the right of the active layer 120.

The gate electrode 140 overlaps with the active layer 120 and extends in a second direction, for example, in a vertical direction. Aspects are not limited thereto. As an example, the first direction may be not the horizontal direction, and/or the second direction may be not the vertical direction. As an example, the first direction may intersect with, be orthogonal to or in parallel with the second direction.

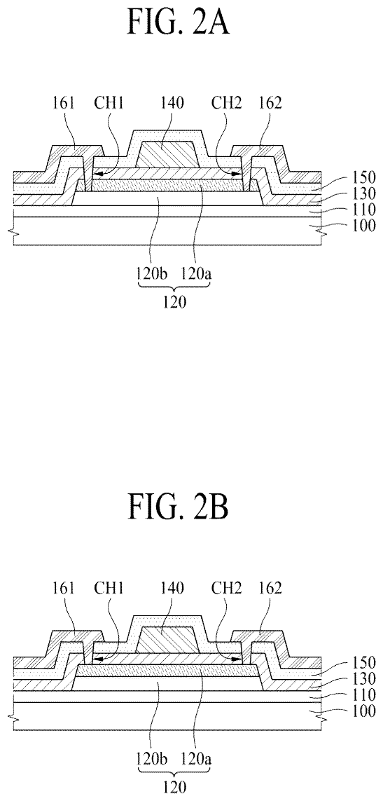

Meanwhile, cross-sectional views of FIGS. 2A to 6 correspond to cross-sectional views cut along I-I′ of FIG. 1 according to an exemplary aspect of the present disclosure.

FIG. 2A is a cross-sectional view of a thin film transistor substrate according to an exemplary aspect of the present disclosure.

The thin film transistor substrate according to an exemplary aspect of present disclosure includes a substrate 100, a buffer layer 110, an active layer 120, a gate insulating film 130, a gate electrode 140, an interlayer insulating film 150, a source electrode 161, and a drain electrode 162. Meanwhile, the thin film transistor according to FIG. 2A relates to a top gate structure in which the gate electrode 140 is provided on the active layer 120.

The substrate 100 may be made of glass or plastic, without being limited thereto. In particular, the substrate 100 may be made of transparent plastic having flexible characteristics, for example, polyimide. When polyimide is used as the substrate 100, heat-resistant polyimide that may withstand high temperatures may be used considering that a high-temperature deposition process is performed on the substrate 100. Aspects are not limited thereto. As an example, an opaque or semitransparent material or a material having rigidity, such as metal, glass, etc. may be used as the substrate 100.

The buffer layer 110 is formed on the substrate 100. The buffer layer 110 may protect the active layer 120 by blocking air and moisture. The buffer layer 110 may be made of an inorganic insulating material such as silicon oxide, silicon nitride, or metal oxide, but is not limited thereto and may be made of an organic insulating material. The buffer layer 110 may be formed of a single layer or may be formed of a plurality of layers.

The active layer 120 is formed on the buffer layer 110.

The active layer 120 may include a semiconductor material, for example, an oxide semiconductor material. The oxide semiconductor material is, for example, an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZO (GaZnO)-based oxide semiconductor material, a ITZO (InSnZnO)-based oxide semiconductor material and a FIZO(FeInZnO)-based oxide semiconductor, without being limited thereto.

The active layer 120 may include a first active layer 120a and a second active layer 120b.

The first active layer 120a includes a crystalline oxide semiconductor material, and the second active layer 120b includes an amorphous oxide semiconductor material.

In this way, the thin film transistor substrate according to an exemplary aspect of present disclosure may secure high mobility and secure a threshold voltage Vth in the positive (+) direction by having multiple active layers 120a, 120b, especially a first active layer 120a including a crystalline oxide semiconductor material and a second active layer 120b including an amorphous oxide semiconductor material. Hereinafter this will be described in detail below.

The second active layer 120b is formed on the buffer layer 110, and the first active layer 120a is formed on the second active layer 120b. That is, the second active layer 120b is formed under the first active layer 120a, so that the second active layer 120b is located farther from the gate electrode 140 than the first active layer 120a.

In the case of an oxide semiconductor, oxygen vacancies may increase the number of charge carriers. Therefore, the higher the oxygen vacancy in the oxide semiconductor, the higher the mobility of the charge carrier. In this case, for the same oxide semiconductor material, the oxide semiconductor material formed of amorphous material generates more oxygen vacancy than the oxide semiconductor material formed of crystalline material, thereby increasing the number of charge carriers and thus increasing the mobility of the charge carriers. That is, the quantity of charge carriers directly impacts the mobility of the charge carriers, higher mobility facilitates faster and more efficient charge transportation within the semiconductor, improving its overall performance.

Therefore, when the first active layer 120a and the second active layer 120b include the same oxide semiconductor material, the mobility of the second active layer 120b including the amorphous oxide semiconductor material may be higher than that of the first active layer 120a including the crystalline oxide semiconductor material.

According to an exemplary aspect of the present disclosure, the second active layer 120b includes an oxide semiconductor material having high mobility, and the first active layer 120a includes an oxide semiconductor material having lower mobility than the second active layer 120b. In this case, the thin film transistor according to the aspect of present disclosure may realize high mobility characteristics when the main channel is formed in the second active layer 120b by forming the oxide semiconductor material included in the second active layer 120b in an amorphous state and the oxide semiconductor material included in the first active layer 120a in a crystalline state. In essence, this design utilizes the differences in atomic structure (amorphous vs crystalline) and the resulting differences in mobility to enhance the performance of the thin-film transistor in accordance with the aspect in the present disclosure. The high mobility in the second active layer 120b may be harnessed when the main channel is formed there, allowing for faster and more efficient electrical performance.

As a result, when the thin film transistor substrate according to an exemplary aspect of present disclosure is turned on, it is much desirable that the second active layer 120b having relatively higher mobility of the charge carrier than the first active layer 120a may function as a main channel for charge carrier movement.

In this way, in order for the second active layer 120b to function as a main channel for charge carrier movement, a band gap energy of the second active layer 120b may be lower than a band gap energy of the first active layer 120a. The lower the band gap energy, the narrower the distance between the valence band and the conductive band, resulting in higher electron conductivity. Accordingly, the electronic conductivity of the second active layer 120b is formed to be higher than that of the first active layer 120a.

Finally, by forming the band gap energy of the second active layer 120b lower than the band gap energy of the first active layer 120a, when the thin film transistor substrate according to an exemplary aspect of present disclosure is turned on, the main channel is formed in the second active layer 120b. In this case, as described above, since the second active layer 120b has high charge carrier mobility, the thin film transistor according to an exemplary aspect of present disclosure may have high mobility characteristics.

The second active layer 120b may include at least one oxide semiconductor material of the amorphous CuO-based oxide semiconductor material, an IZO(InZnO)-based oxide semiconductor material, a SnO-based oxide semiconductor material, an InO-based oxide semiconductor material, and an IGZO(InGaZnO)-based oxide semiconductor material. For example, the second active layer 120b may include an amorphous IZO(InZnO)-based oxide semiconductor material, without being limited thereto. in this case, the bandgap energy of the IZO-based oxide semiconductor material is 2.6 eV or more and 2.8 eV or less, for example, 2.7 eV. Meanwhile, the configuration of the second active layer 120b is not limited to the amorphous IZO-based oxide semiconductor material.

In addition, in order for the second active layer 120b to function as the main channel for charge carrier movement, an electrical resistance of the second active layer 120b may be lower than an electrical resistance of the first active layer 120a. In the structure of the active layer 120 of the multilayer film, a charge carrier may move to a region having a low electrical resistance.

As a result, the electrical resistance of the second active layer 120b is lower than that of the first active layer 120a, so when the thin film transistor substrate according to an exemplary aspect of present disclosure is turned on, the main channel is formed in the second active layer 120b. In this case, as described above, since the second active layer 120b has high charge carrier mobility, the thin film transistor according to an exemplary aspect of present disclosure may have high mobility characteristics.

The second active layer 120b may include at least one oxide semiconductor material of the amorphous CuO-based oxide semiconductor material, an IZO(InZnO)-based oxide semiconductor material, a SnO-based oxide semiconductor material, an InO-based oxide semiconductor material, and an IGZO(InGaZnO)-based oxide semiconductor material, without being limited thereto. For example, the second active layer 120b may include an amorphous IZO(InZnO)-based oxide semiconductor material. and the electrical resistance of the IZO-based oxide semiconductor material may be 0.7 kΩ/□ or more and 1 kΩ/□ or less.

As described above, as the band gap energy of the second active layer 120b is smaller than the band gap energy of the first active layer 120a and/or the electrical resistance of the second active layer 120b is lower than the electrical resistance of the first active layer 120a, when the thin film transistor substrate is turned on, the main channel is formed in the second active layer 120b.

Accordingly, the charge carrier moves through the second active layer 120b having high mobility including an amorphous oxide semiconductor. As a result, the thin film transistor substrate according to an exemplary aspect may realize high mobility.

Hereinafter, a method of forming the second active layer 120b according to an exemplary aspect of the present disclosure will be described.

The second active layer 120b includes at least one of an amorphous CuO-based semiconductor material, an IZO(InZnO)-based semiconductor material, a SnO-based semiconductor material, an InO-based semiconductor material, an IGZO(InGaZnO)-based semiconductor material, a ZnO-based semiconductor material, a SnO-based semiconductor material, and a GO(GaO)-based semiconductor material, without being limited thereto. As an example, the second active layer 120b may be formed by metal organic chemical vaporized deposition (MOCVD) or Sputtering method, without being limited thereto.

According to an exemplary aspect of the present disclosure, the second active layer 120b including the amorphous oxide semiconductor material may be formed by the metal organic chemical vaporized deposition (MOCVD)

For example, when the second active layer 120b includes an amorphous IZO-based oxide semiconductor material, the second active layer 120b may be formed by the MOCVD method using a source material containing indium In, a source material containing zinc Zn, and a reactive material containing oxygen O₂.

According to another exemplary aspect of present disclosure, the second active layer 120b including the amorphous oxide semiconductor material may be formed by the sputtering method.

For example, if the second active layer 120b contains an amorphous IZO-based oxide semiconductor material, a sputtering method using a target including indium In, zinc Zn, and oxygen O₂ may be used, and the second active layer 120b including the amorphous IZO oxide semiconductor material may be formed.

The first active layer 120a is formed on the second active layer 120b, and thus the first active layer 120a is formed closer to the gate electrode 140 than the second active layer 120b.

By forming in this way, the first active layer 120a may be formed in contact with the gate insulating film 130 provided at the bottom of the gate electrode 140. in this case, since the first active layer 120a contains a material of crystalline with a relatively small number of charge carriers, charges trapped at the interface formed between the first active layer 120a and the gate insulating film 130 may be reduced or minimized.

Specifically, the first active layer 120a includes a crystalline oxide semiconductor.

Since the first active layer 120a includes a crystalline oxide semiconductor, a Positive Bias Temperature Stress (PBTS) reliability may be improved even when a process of securing a threshold voltage Vth of a thin film transistor including the first active layer 120a in a positive (+) direction is performed.

Specifically, a performance of the thin film transistor may be degraded due to long-term use, and a PBTS reliability may be measured as an indicator that may confirm this. In this case, as the change amount ΔVth of the threshold voltage of the thin film transistor substrate is constant, the PBTS reliability may be higher.

As the thin film transistor is turned on, a charge carrier may be trapped at the interface formed between the active layer 120 and the gate insulating film 130. The threshold voltage Vth of the thin film transistor may be changed by the trapped charge carrier. Specifically, when the amount of charge trapped at the interface formed between the active layer 120 and the gate insulating film 130 changes, the threshold voltage Vth of the thin film transistor changes.

Thin film transistors including active layers 120 including high mobility oxide semiconductors are easy to form threshold voltages Vth in the negative (−) direction, and it is difficult to secure the threshold voltages Vth in the positive (+) direction. Therefore, a method to secure the threshold voltage Vth in the positive (+) direction is required, and for example, a method such as using an active layer with high oxygen content or a gate insulating film with high oxygen content may be considered.

However, if the threshold voltage Vth is secured in the positive (+) direction by increasing the oxygen content or oxygen partial pressure, the amount of charge trapped between the active layer and the gate insulating film increases, and thereby reducing the PBTS reliability of the thin film transistor substrate.

The first active layer 120a according to an exemplary aspect of present disclosure includes a crystalline oxide semiconductor between the gate insulating film 130 and the second active layer 120b, so that the thin film transistor substrate of present disclosure including the first active layer 120a may improve PBTS reliability.

Specifically, crystalline oxide semiconductors may reduce or minimize charge traps generated inside or at the interface of the active layer. Since the first active layer 120a includes a crystalline oxide semiconductor, a charge carrier trapped at an interface formed between the first active layer 120a and the gate insulating film 130 may be reduced or minimized.

Therefore, the thin film transistor substrate according to an exemplary aspect of the present disclosure may secure improved PBTS reliability even in a process of securing a threshold voltage Vth in a positive (+) direction.

According to an exemplary aspect of the present disclosure, the first active layer 120a includes one of a crystalline CuO-based oxide semiconductor material, an IZO (InZnO)-based oxide semiconductor material, an SnO-based oxide semiconductor material, an InO-based oxide semiconductor material, an IGZO (InGaZnO)-based oxide semiconductor material, a ZnO-based oxide semiconductor material, and an SnO-based oxide semiconductor material, without being limited thereto. for example, the first active layer 120a may include a crystalline IGZO-based oxide semiconductor material, in this case a band gap energy of the IGZO-based oxide semiconductor material is 3.0 eV or more and 3.2 eV or less, for example 3.1 eV. Meanwhile, the configuration of the first active layer 120a is not limited to the crystalline IGZO-based oxide semiconductor material.

According to an exemplary aspect of present disclosure, for example, when the first active layer 120a includes a crystalline IGZO-based oxide semiconductor and the second active layer 120b includes an IZO-based oxide semiconductor, as described above, because the first active layer 120a including a crystalline IGZO-based oxide semiconductor material has a bandgap energy of 3.0 eV to 3.2 eV, and the second active layer 120b including an amorphous IZO-based oxide semiconductor material has a bandgap energy of 2.6 eV to 2.8 eV, when the thin film transistor according to an exemplary aspect is turned-on, a main channel is formed in the second active layer 120b to move the charge carrier.

In addition, according to an exemplary aspect of present disclosure, the first active layer 120a includes at least one of a crystalline CuO-based oxide semiconductor material, an IZO (InZnO)-based oxide semiconductor material, a SnO-based oxide semiconductor material, an InO-based oxide semiconductor material, an IGZO (InGaZnO)-based oxide semiconductor material, a ZnO-based oxide semiconductor material, a SnO-based oxide semiconductor material and a GO (GaO)-based oxide semiconductor material, for example an IGZO (InGaZnO)-based oxide semiconductor material, and an electrical resistance of the IGZO-based oxide semiconductor material may be 2 kΩ/□ or more and kΩ/□ or less.

According to an exemplary aspect of present disclosure, for example, when the first active layer 120a may include a crystalline IGZO-based oxide semiconductor material, and the second active layer 120b may include an amorphous IZO-based oxide semiconductor material, the first active layer 120a including the crystalline IGZO-based oxide semiconductor material has the electrical resistance of 2 kΩ/□ or more and 3 kΩ/□ or less, and the second active layer 120b including the amorphous IZO-base oxide semiconductor material has the electrical resistance of 0.7 kΩ/□ or more and 1 kΩ/□ or less, accordingly, when the thin film transistor substrate according to an exemplary aspect of present disclosure is turned-on, a main channel is formed in the second active layer 120b to move the charge carrier.

According to an exemplary aspect of the present disclosure, a thickness of the first active layer 120a may be smaller than a thickness of the second active layer 120b.

By forming in this way, when the thin film transistor according to the aspect is turned-on, the main channel may be well formed in the second active layer 120b. On the other hand, if the first active layer 120a is too thick compared to the second active layer 120b, since the voltage applied from the gate electrode 140 is not well transmitted, a main channel may not be well formed in the second active layer 120b.

Therefore, the thickness of the first active layer 120a may be thinner than that of the second active layer 120b. Aspects are not limited thereto. As an example, the thickness of the first active layer 120a may also be equal to or greater than the thickness of the second active layer 120b.

Hereinafter, a method of forming the first active layer 120a according to an exemplary aspect of the present disclosure will be described.

According to an exemplary aspect of present disclosure, the first active layer 120a includes a crystalline oxide semiconductor, for example, an IGZO (InGaZnO)-based oxide semiconductor material, and the first active layer 120a is formed by a spatiotemporally divided atomic layer deposition STALD, without being limited thereto.

The spatiotemporally divided atomic layer deposition STALD method refers to a process of stacking one layer with a source material containing a first metal and a reactive material containing oxygen, and then stacking another layer with a source material containing a second metal and a reactive material containing an oxygen and repeating the same. On the other hand, the metal source material is not limited to two, and a larger number of metal source materials may be used according to the knowledge of those skilled in the art. When an oxide semiconductor is formed by the spatiotemporally divided atomic layer deposition STALD method, a crystalline oxide semiconductor may be formed by stacking each metal oxide layer. Meanwhile, the space in which the spatiotemporally divided atomic layer deposition STALD method may be performed, for example, the atmosphere inside the chamber may be set from 300 Celsius degrees to 400 Celsius degrees, without being limited thereto.

According to an exemplary aspect of the present disclosure, the first active layer 120a may include a crystalline oxide semiconductor material, and for example, the first active layer 120a may include a crystalline IGZO-based oxide semiconductor material. In this case, the IGZO-based oxide semiconductor material may be formed of crystalline material, for example, by the spatiotemporally divided atomic layer deposition STALD method.

Specifically, after the second active layer 120b is formed on the buffer layer 110, and a source material including indium In, a source material including Gallium Ga, a source material including zinc Zn and a reactive material O₂ may be sequentially stacked on the second active layer 120b by the spatiotemporally divided atomic layer deposition STALD method. Accordingly the first active layer 120a may be formed of crystalline material on the second active layer 120b.

For example, the source material containing indium In, the reactive material including oxygen O₂, the source material including gallium Ga, the reactive material including oxygen O₂, the source material including zinc Zn, and the reactive material including oxygen O₂ are repeatedly deposited on the bottom of the first active layer 120a by spatiotemporally divided atomic layer deposition STALD. Accordingly the first active layer 120a including the crystalline IGZO-based oxide semiconductor material may be formed.

The active layer 120 may overlap with the gate electrode 140, and a portion of the active layer 120 may be protected by the gate electrode 140.

The top gate thin film transistor according to an exemplary aspect of the present disclosure may conduct an ion doping process on the active layer 120 using the gate electrode 140 as a mask so that a partial region of the ion-doped active layer 120 may be conductorized. After conducting the active layer 120, a portion of the active layer 120 overlapping with the gate electrode 140 is not conductive, and only the remaining portion of the active layer 120 that does not overlap with the gate electrode 140 may be conductive. Aspects are not limited thereto. As an example, a separated mask other than the gate electrode 140 may be used in the ion doping process.

The gate insulating film 130 may be formed on the active layer 120. Specifically, the gate insulating film 130 may be formed on the active layer 120 and the buffer layer 110. As a result, the active layer 120 is formed to be surrounded by the buffer layer 110 and the gate insulating film 130.

In a thin film transistor with a top gate structure like an exemplary aspect of present disclosure, the gate insulating film 130 may be formed on the upper surface of the first active layer 120a.

The gate insulating film 130 may include, but is not limited to, a silicon nitride film SiNx or a silicon oxide film SiOx. The gate insulating film 130 may have a single layer structure or a multilayer layer structure.

The gate electrode 140 may be formed on the gate insulating film 130.

The gate electrode 140 may include at least one of aluminum-based metals such as aluminum Al or aluminum alloy, silver-based metals such as silver Ag or silver alloy, copper-based metals such as copper Cu or copper alloy, molybdenum-based metals such as molybdenum Mo or molybdenum alloy, chromium Cr, tantalum Ta, neodymium Nd, and titanium Ti, without being limited thereto. The gate electrode 140 may have a single layer film structure or a multilayer film structure including at least two conductive films having different physical properties, respectively.

The interlayer insulating film 150 may be formed on the gate electrode 140. Specifically, the interlayer insulating film 150 may be formed on the gate electrode 140 and a portion of the gate insulating film 130, so that the interlayer insulating film 150 and the gate insulating film 130 may surround the gate electrode 140.

the interlayer insulating film 150 insulates between the gate electrode 140 and the source electrode 161, and further insulates between the gate electrode 140 and the drain electrode 162. The interlayer insulating film 150 may be formed of a single layer or a plurality of layers including an inorganic insulating material and/or an organic insulating material.

The interlayer insulating film 150 is provided with a first contact hole CH1 and a second contact hole CH2. The first contact hole CH1 and the second contact hole CH2 may be formed by patterning a portion of the interlayer insulating film 150, a portion of the gate insulating film 130, and a portion of the first active layer 120a.

The source electrode 161 and the drain electrode 162 may be formed on the interlayer insulating film 150.

The source electrode 161 is electrically connected to one side of the second active layer 120b provided in the active layer 120, and/or the drain electrode 162 is electrically connected to another side of the second active layer 120b provided in the active layer 120.

Specifically, the source electrode 161 is connected to one side of the second active layer 120b through the first contact hole CH1 provided in the interlayer insulating film 150, and the drain electrode 162 is connected to another side of the second active layer 120b through the second contact hole CH2 provided in the interlayer insulating film 150. As an example, the first contact hole CH1 may be further provided in the first active layer 120a, and/or the second contact hole CH2 may be further provided in the first active layer 120a.

As described above, the second active layer 120b includes an amorphous oxide semiconductor, and the source electrode 161 and the drain electrode 162 are directly connected to the second active layer 120b, thereby realizing high mobility characteristics of the thin film transistor according to an exemplary aspect of present disclosure. But aspects are not limited thereto. As an example, the source electrode 161 may be electrically connected to one side of the first active layer 120a provided in the active layer 120, without being directly connected to the second active layer 120b, and/or the drain electrode 162 may be electrically connected to another side of the first active layer 120a provided in the active layer 120, without being directly connected to the second active layer 120b.

Hereinafter, a method of manufacturing a thin film transistor substrate having a top gate structure according to an exemplary aspect of the present disclosure will be described.

The thin film transistor according to an exemplary aspect of present disclosure forms a buffer layer 110 on the substrate 100, forms a second active layer 120b on the buffer layer 110, forms a first active layer 120a on the second active layer 120b, forms a gate insulating film 130 on the first active layer 120a, forms a gate electrode 140 on the gate insulating film 130, forms a gate insulating film 150 on the gate electrode 140, and then forms the source electrode 161 and the drain electrode in the first contact hole CH1 and the second contact hole CH2 provided in the interlayer insulating film 150. Meanwhile, the second active layer 120b may be formed through MOCVD as described above, and the first active layer 120a may be formed through spatiotemporally divided atomic layer deposition (STALD) as described above.

FIG. 2B is a cross-sectional view of a thin film transistor substrate according to another exemplary aspect of the present disclosure.

FIG. 2B is the same as the aspect according to FIG. 2A, except that the source electrode 161 and the drain electrode 162 are connected to the first active layer 120a provided in the active layer 120, and thus different configurations will be mainly described below.

According to an exemplary aspect of the present disclosure, the first contact hole CH1 and the second contact hole CH2 may be formed by patterning portions of the interlayer insulating film 150 and the gate insulating film 130. In this case, unlike the aspect of FIG. 2A, the first active layer 120a may not be patterned in the process of forming the first contact hole CH1 and the second contact hole CH2. Accordingly, one side, for example, the left side of the first active layer 120a of the active layer 120 may be exposed by the first contact hole CH1, and another side, for example, the right side of the first active layer 120a of the active layer 120 may be exposed by the second contact hole CH2.

Therefore, according to the aspect of present disclosure, the source electrode 161 may be electrically connected to one side of the first active layer 120a through the first contact hole CH1, and the drain electrode 162 may be electrically connected to another side of the first active layer 120a through the second contact hole CH2.

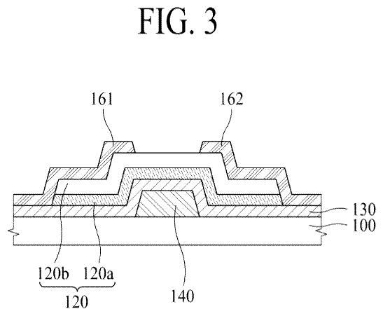

FIG. 3 is a cross-sectional view of a thin film transistor substrate according to another exemplary aspect of the present disclosure.

FIG. 2A relates to a top gate structure in which the gate electrode 140 is formed above the active layer 120, whereas FIG. 3 relates to a bottom gate structure in which the gate electrode 140 is formed below the active layer 120.

Since the thin film transistor substrate according to FIG. 3 is the same as the thin film transistor substrate according to FIG. 2A except for the order in which each layer is stacked, different configurations will be mainly described below.

The thin film transistor substrate according to FIG. 3 includes a substrate 100, a gate electrode 140, a gate insulating film 130, an active layer 120, a source electrode 161, and a drain electrode 162.

Specifically, the gate electrode 140 is provided on the substrate 100, the gate insulating film 130 is provided on the gate electrode 140, the active layer 120 including a first active layer 120a and a second active layer 120b is provided on the gate insulating film 130, the source electrode 161 is formed on one side, for example, the left side of the active layer 120 and the drain electrode 162 is formed on another side, for example, the right side of the active layer 120.

The first active layer 120a is formed on the gate insulating film 130.

The first active layer 120a is formed closer to the gate electrode 140 than the second active layer 120b.

By forming in this way, the first active layer 120a is formed in contact with the gate insulating film 130 provided on the upper end of the gate electrode 140. Accordingly, charges trapped at an interface formed between the first active layer 120a and the gate insulating film 130 may be reduced or minimized.

The second active layer 120b is formed on the first active layer 120a. Accordingly, the second active layer 120b is located farther from the gate electrode 140 than the first active layer 120a.

As a result, the thin film transistor substrate according to an exemplary aspect of the present disclosure may obtain improved reliability even when a process of securing a threshold voltage Vth of a thin film transistor including the first active layer 120a in a positive (+) direction is performed. In addition, by including the second active layer 120b, the thin film transistor may form a main channel having high mobility. That is, the thin film transistor having a bottom gate structure according to FIG. 3 may be implemented as an element having high mobility and high reliability.

Hereinafter, a method of manufacturing a thin film transistor substrate having a bottom gate structure according to an exemplary aspect of the present disclosure will be described.

In accordance with the thin film transistor according to an exemplary aspect of present disclosure, the gate electrode 140 is formed on the substrate 100, the gate insulating film 130 is formed on the gate electrode 140, the first active layer 120a is formed on the gate insulating film 130, the second active layer 120b is formed on the first active layer 120a, and the source electrode 161 and the drain electrode 162 is formed on the second active layer 120b. in this case, the second active layer 120b may be formed through MOCVD as described above, and the first active layer 120a may be formed through spatiotemporally divided atomic layer deposition (STALD) as described above.

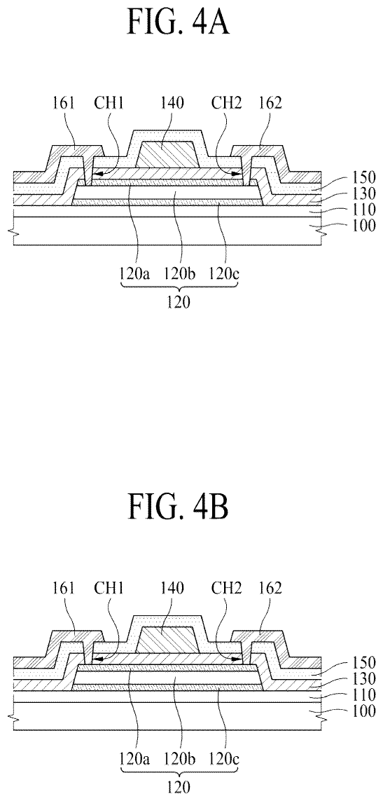

FIG. 4A is a cross-sectional view of a thin film transistor substrate according to another exemplary aspect of the present disclosure.

FIG. 4A relates to a top gate structure in which the gate electrode 140 is formed above the active layer 120, as in the case of FIG. 2A described above.

Since the thin film transistor of FIG. 4A is the same as the thin film transistor of FIG. 2A except that the active layer 120 includes a third active layer 120c, different configurations will be mainly described below.

As shown in FIG. 4A, the active layer 120 includes the first active layer 120a, the second active layer 120b, and the third active layer 120c.

The third active layer 120c is formed on the buffer layer 110, the second active layer 120b is formed on the third active layer 120c, and the first active layer 120a is formed on the second active layer 120b.

Therefore, the third active layer 120c may be formed at a position farther than the gate electrode 140 than the first active layer 120a and the second active layer 120b.

Similar to the first active layer 120a described above, the third active layer 120c may include a crystalline material. Specifically, the third active layer 120c may include a crystalline oxide semiconductor material.

Since the third active layer 120c includes a crystalline oxide semiconductor material, hydrogen diffused from the buffer layer 110 may be blocked. By blocking hydrogen diffused from the buffer layer 110, the third active layer 120c may protect the second active layer 120b including an amorphous oxide semiconductor material.

Since the third active layer 120c protects the second active layer 120b, the threshold voltage Vth of the thin film transistor may not be shifted in a negative (−) direction.

According to another exemplary aspect of the present disclosure, the third active layer 120c may include at least one of a CuO-based oxide semiconductor material, an IZO (InZnO)-based oxide semiconductor material, an SnO-based oxide semiconductor material, an InO-based oxide semiconductor material, an IGZO (InGaZnO)-based oxide semiconductor material, a ZnO-based oxide semiconductor material, and a GO (GaO)-based oxide semiconductor material, without being limited thereto. for example, the third active layer 120c may include crystalline IGZO-based oxide semiconductor material, in this case, a band gap energy of the IGZO-based oxide semiconductor material is 3.0 eV or more and 3.2 eV or less, for example, 3.1 eV. Also, the band gap energy of the third active layer 120c, for example, may be the same as that of the first active layer 120a. Meanwhile, the configuration of the third active layer 120c is not limited to a crystalline IGZO-based oxide semiconductor material. As an example, the third active layer 120c may include different material from that of the first active layer 120a, and/or may have different band gap energy from that of the first active layer 120a.

In addition, according to an exemplary aspect of present disclosure, the third active layer 120c includes at least one of a crystalline CuO-based oxide semiconductor material, IZO (InZnO)-based oxide semiconductor material, SnO-based oxide semiconductor material, InO-based oxide semiconductor material, IGZO (InGaZnO)-based oxide semiconductor material, ZnO-based oxide semiconductor material, and GO (GaO)-based oxide semiconductor material. For example, the third active layer 120c may include a crystalline IGZO-based oxide semiconductor material, and an electrical resistance of the IGZO-based oxide semiconductor material may be 2 kΩ/□ or more and 3 kΩ/□ or less. In this case, the electrical resistance of the third active layer 120c may be the same as that of the first active layer 120a, without being limited thereto.

According to another exemplary aspect of present disclosure, since the third active layer 120c includes a crystalline oxide semiconductor, for example, an IGZO-based oxide semiconductor, and the second active layer 120b includes an amorphous oxide semiconductor, for example, an IZO-based oxide semiconductor, the third active layer 120c may have higher band gap energy and electrical resistance than the second active layer 120b. As a result, when the thin film transistor is turned-on, a main channel is formed in the second active layer 120b, where the charge carrier moves.

The third active layer 120c may be made of the same material as the first active layer 120a, and may be formed by the same spatiotemporally divided atomic layer deposition (STALD) method, without being limited thereto.

FIG. 4B is a cross-sectional view of a thin film transistor substrate according to another exemplary aspect of the present disclosure.

FIG. 4B is the same as the aspect according to FIG. 4A except that the source electrode 161 and the drain electrode 162 are connected to the first active layer 120a provided in the active layer 120, and thus different configurations will be mainly described below.

According to an exemplary aspect of present disclosure, unlike that the source electrode 161 and the drain electrode 162 is connected to the one side and another side of the second active layer 120b respectively, through the first contact hole CH1 and the second contact hole CH2 in the thin film transistor according to the aspect of FIG. 4A, the source electrode 161 may be electrically connected to one side of the first active layer 120a through the first contact hole CH1 and the drain electrode may be electrically connected to another side of the first active layer 120b through the second contact hole CH2, without being directly connected to the second active layer 120b.

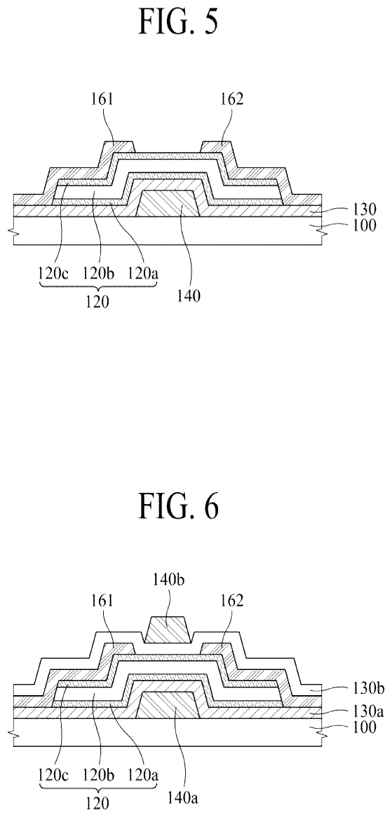

FIG. 5 is a cross-sectional view of a thin film transistor substrate according to another exemplary aspect of the present disclosure.

FIG. 4A relates to a top gate structure in which the gate electrode 140 is formed above the active layer 120, and FIG. 5 relates to a bottom gate structure in which the gate electrode 140 is formed below the active layer 120.

Since the thin film transistor substrate according to FIG. 5 is the same as the thin film transistor substrate according to FIG. 4A except for the order in which each layer is stacked, only different configurations will be described below.

The thin film transistor substrate according to FIG. 5 includes a substrate 100, a gate electrode 140, a gate insulating film 130, an active layer 120, a source electrode 161, and a drain electrode 162.

Specifically, the gate electrode 140 is provided on the substrate 100, the gate insulating film 130 is provided on the gate insulating film 130, the active layer 120a including a first active layer 120a, a second active layer 120b and a third active layer 120c is provided on the gate insulating film 130, the source electrode 161 is provided on one side, for example, the left side of the active layer 120 and the drain electrode 162 is provided on another side, for example, the right side of the active layer 120.

The first active layer 120a is formed on the gate insulating film 130.

The first active layer 120a is formed closer to the gate electrode 140 than the second active layer 120b.

By forming in this way, the first active layer 120a is formed in contact with the gate insulating film 130 provided on the upper end of the gate electrode 140. Accordingly, charges trapped at an interface formed between the first active layer 120a and the gate insulating film 130 may be reduced or minimized.

The second active layer 120b is formed on the first active layer 120a. Accordingly, the second active layer 120b is located farther from the gate electrode 140 than the first active layer 120a.

The third active layer 120c is formed on the second active layer 120b. Accordingly, the third active layer 120c is located farther from the gate electrode 140 than the first active layer 120a and the second active layer 120b.

The thin film transistor according to an exemplary aspect of the present disclosure may obtain improved positive bias temperature stress (PBTS) reliability even when a process of securing a threshold voltage Vth of the thin film transistor including the first active layer 120a in a positive (+) direction is performed. In addition, by including the second active layer 120b, a main channel having high mobility may be formed in the thin film transistor. That is, the thin film transistor having a bottom gate structure according to FIG. 5 may be implemented as an element having high mobility and high reliability.

FIG. 6 is a cross-sectional view of a thin film transistor substrate according to another exemplary aspect of the present disclosure.

The thin film transistor substrate according to FIG. 6 is the same as the thin film transistor substrate according to FIG. 5, except that the thin film transistor substrate according to FIG. 6 relates to a double gate electrode. Hereinafter, a configuration different from that of FIG. 5 will be mainly described.

As shown in FIG. 6, the gate insulating film 130 includes a first gate insulating film 130a and a second gate insulating film 130b. In this case, the first gate insulating film 130a is the same as or similar to the gate insulating film 130 of the thin film transistor substrate according to FIG. 5.

The second gate insulating film 130b is formed on the active layer 120, the source electrode 161, and the drain electrode 162. Therefore, the second gate insulating film 130b insulates the active layer 120, the source electrode 161, and the drain electrode 162 with the upper gate electrode 140b provided on the second gate insulating film 130b.

The second gate insulating film 130b may include, but is not limited thereto, a silicon nitride layer SiNx or a silicon oxide layer SiOx. The second gate insulating film 130b may have a single layer structure or a multilayer layer structure.

As shown in FIG. 6, the gate electrode 140 includes a lower gate electrode 140a and an upper gate electrode 140b. In this case, the lower gate electrode 140a is the same as or similar to the gate electrode 140 of FIG. 5.

The upper gate electrode 140b is formed on the second gate insulating film 130b.

The upper gate electrode 140b may include at least one of an aluminum-based metal such as aluminum Al or aluminum alloy, a silver-based metal such as silver Ag or silver alloy, a copper-based metal such as copper Cu or copper alloy, a molybdenum-based metal such as molybdenum Mo or molybdenum alloy, tantalum Ta, neodymium Nd, and titanium Ti, without being limited thereto. The second gate electrode 140b may have a single layer structure or a multilayer structure including at least two conductor layers having different physical properties.

The third active layer 120c includes a crystalline material. Specifically, the third active layer 120c includes a crystalline oxide semiconductor material.

The third active layer 120c is formed on the second active layer 120b, and thus the third active layer 120c is formed closer to the upper gate electrode 140b than the first active layer 120a and the second active layer 120b.

By forming in this way, the third active layer 120c may be formed to be in contact with the second gate insulating film 130b provided under the upper gate electrode 140b.

Therefore, the charge trapped at the interface formed between the third active layer 120c and the second gate insulating film 130b including a crystalline oxide semiconductor material may be reduced or minimized.

Since the third active layer 120c according to another exemplary aspect of present disclosure includes a crystalline oxide semiconductor material and is provided between the second gate insulating film 130b and the second active layer 120b, the thin film transistor substrate of present disclosure including the third active layer 120c may obtain improved PBTS reliability.

Therefore, the thin film transistor substrate according to another exemplary aspect of the present disclosure may secure improved PBTS reliability even in a process of securing a threshold voltage Vth in a positive (+) direction.

According to another exemplary aspect of the present disclosure, a thickness of the third active layer 120c may be smaller than a thickness of the second active layer 120b. A thickness of the third active layer 120c may be the same as or similar to a thickness of the first active layer 120a, without being limited thereto.

By forming in this way, when the thin film transistor according to the aspect of present disclosure is turned-on, the main channel may be well formed in the second active layer 120b.

Meanwhile, although not illustrated, one gate electrode 140 may be changed into a double gate electrode in the thin film transistor substrate according to FIG. 4A. In this case, a lower gate electrode may be added between the substrate 100 and the buffer layer 110 in the thin film transistor substrate according to FIG. 4A described above.

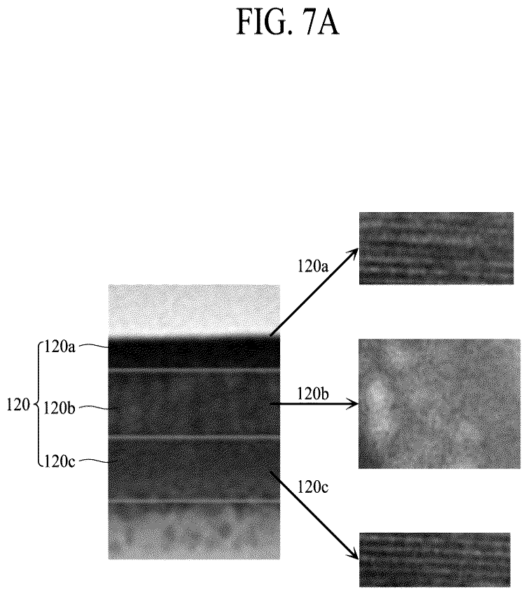

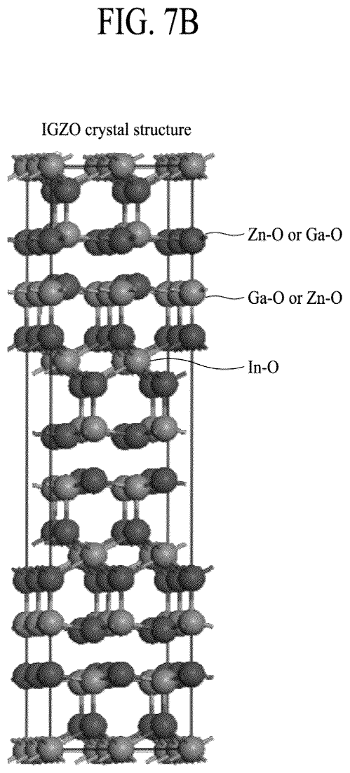

FIG. 7A is a transmission electron microscope (TEM) photograph of an active layer provided in a thin film transistor substrate in accordance with an exemplary aspect of present disclosure.

The active layer 120 according to FIG. 7A is manufactured by sequentially stacking the third active layer 120c, the second active layer 120b, and the first active layer 120a.

The TEM photograph on the left shows the active layer 120 formed on the substrate 100, and the TEM photograph on the right shows the first active layer 120a, the second active layer 120b, and the third active layer 120c, respectively.

As described above in FIGS. 2A and 3, the first active layer 120a and the third active layer 120c are formed by spatiotemporally divided ALD (STALD), and may include an IGZO (InGaZnO)-based oxide semiconductor material. In addition, the second active layer 120b is formed by MOCVD and includes an IZO (InZnO)-based oxide semiconductor material.

As the TEM photographs of the first active layer 120a and the third active layer 120c show that the deposited material has multiple stacked structures with regularity in a predetermined direction, and from this, it may be seen that the first active layer 120a and the third active layer 120c are formed of a crystalline material.

As shown by the TEM photograph of the second active layer 120b, it may be seen that a deposited material is irregularly formed without a specific direction, and from this, it may be seen that the second active layer 120b is formed of an amorphous material.

The thin film transistor according to the aspect of present disclosure may be implemented as a device with improved reliability even when a process of securing a threshold voltage Vth in a positive (+) direction is performed by the first active layer 120a and the third active layer 120c made of crystalline material, and may be implemented as a device having high mobility by the second active layer 120b made of amorphous material.

FIG. 7B is a schematic diagram showing an atomic model of an active layer included in a thin film transistor substrate according to another exemplary aspect of the present disclosure, and a schematic diagram showing an atomic model of the first active layer or the third active layer of FIG. 6A.

The atomic model shown in FIG. 7B is an atomic model of a crystalline IGZO (InGaZnO)-based oxide semiconductor material included in the first active layer 120a or the third active layer 120c.

Using spatiotemporally divided atomic layer deposition (STALD), Crystalline IGZO-based oxide semiconductors may be formed by stacking source materials containing indium In and reactant materials containing oxygen O₂, source materials containing gallium Ga and reactant materials containing oxygen O₂, source materials containing zinc Zn, and reactant materials containing oxygen O₂ in an appropriate order.

For example, as shown in FIG. 7B, the crystalline IGZO-based oxide semiconductor is deposited by the spatiotemporally divided atomic layer deposition (STALD), and an indium oxide In—O layer, a gallium oxide Ga—O layer, and a zinc oxide Zn—O layer are repeatedly formed. For example, the gallium oxide Ga—O layer is provided on the indium oxide In—O layer, the zinc oxide Zn—O layer is provided on the gallium oxide Ga—O layer, and the indium oxide In—O layer is repeatedly provided on the zinc oxide Zn—O layer to form a crystalline IGZO-based oxide semiconductor.

Alternatively, the zinc oxide Zn—O layer may be provided on the indium oxide In—O layer, the gallium oxide Ga—O layer may be provided on the zinc oxide Zn—O layer, and the indium oxide In—O layer may be repeatedly provided on the gallium oxide Ga—O layer to form a crystalline IGZO oxide-based semiconductor.

Meanwhile, the order in which the metal oxide layer is repeated is not limited thereto and may be variously changed according to knowledge in the art.

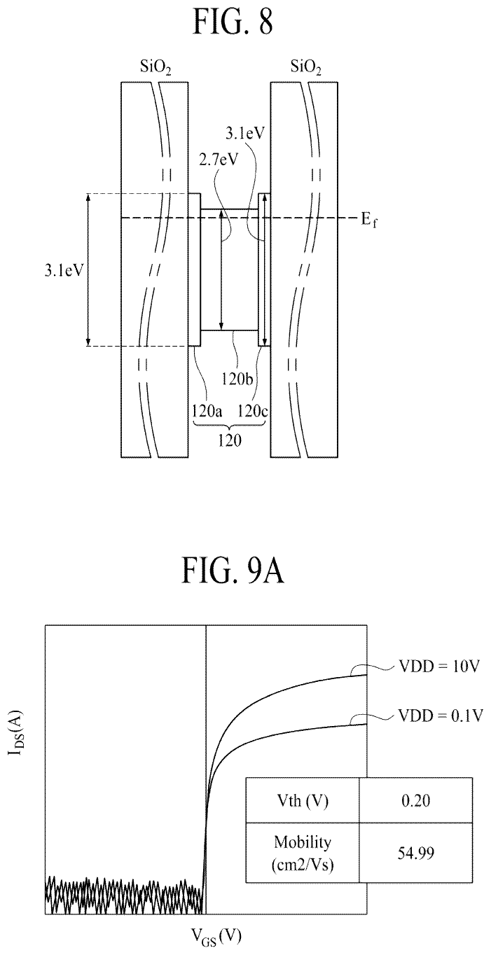

FIG. 8 is a graph illustrating energy levels for each layer of a thin film transistor according to an exemplary aspect of the present disclosure.

As shown in FIG. 8, the active layer 120 is formed between the silicon oxide layers SiO₂. Specifically, between the silicon oxide film SiO₂, the active layer 120 is provided with the first active layer 120a, the second active layer 120b, and the third active layer 120c in order from left to right.

According to an exemplary aspect of present disclosure, for example, the silicon oxide film SiO₂ formed on the left side of the first active layer 120a may be a gate insulating film 130, and the silicon oxide film SiO₂ formed on the right side of the third active layer 120c may be a buffer layer 110.

According to another exemplary aspect of present disclosure, for example, the silicon oxide film SiO₂ formed on the left side of the first active layer 120a may be the first gate insulating film 130a, and the silicon oxide film SiO₂ formed on the right side of the third active layer 120c may be the second gate insulating film 130b.

According to an exemplary aspect of present disclosure, the first active layer 120a and the third active layer 120c include a crystalline IGZO (InGaZnO)-based oxide semiconductor material, and the second active layer 120b includes an amorphous IZO (InZnO)-based oxide semiconductor material.

A crystalline IGZO (InGaZnO)-based oxide semiconductor material, for example, has a bandgap energy of 3.1 eV, and an amorphous IZO (InZnO)-based oxide semiconductor material, for example, has a bandgap energy of 2.7 eV.

Since the Fermi level Ef of the active layer 120 is formed closest to the conductive band of the second active layer 120b including an amorphous IZO-based oxide semiconductor material, a main channel is formed only in the second active layer 120b when the thin film transistor according to an exemplary aspect of present disclosure is turned-on. As an example, the Fermi level Ef of the active layer 120 may be formed closer to the conductive band of the second active layer 120b than conductive band of the first active layer 120a and the third active layer 120c. As an example, the Fermi level Ef of the active layer 120 may be lower than the conductive band of the second active layer 120b, and may be higher than the valence band of the second active layer 120b. As an example, the Fermi level Ef of the active layer 120 may be closer to the conductive band of the second active layer 120b than to the valence band of the second active layer 120b.

As described above, since the second active layer 120b in which the main channel is formed includes an amorphous high mobility oxide semiconductor material, the thin film transistor according to an exemplary aspect of the present disclosure has high mobility characteristics.

On the other hand, even if the Fermi level Ef of the active layer 120 is formed closest to the conductive band of the second active layer 120b, if the thickness of the first active layer 120a and the third active layer 120c is too thick, it may be difficult to form an electric field for forming a main channel in the second active layer 120b. Therefore, the thickness of the second active layer 120b may be greater than the thickness of the first active layer 120a and the third active layer 120c.

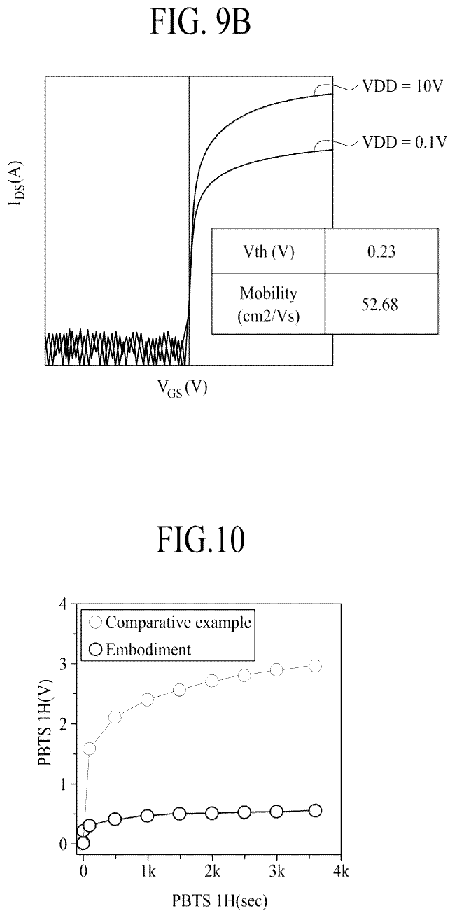

FIG. 9A is a V_{GS}-I_{DS} graph of a thin film transistor substrate according to another exemplary aspect of the present disclosure.

FIG. 9A is a V_{GS}-I_{DS} graph of a thin film transistor substrate according to another exemplary aspect of the present disclosure, and FIG. 9B is a V_{GS}-I_{DS} graph of a thin film transistor substrate according to a comparative example. In this case, FIGS. 9A and 9B each illustrate a transfer curve when 10 V is applied to a high power line VDD and a transfer curve when 0.1 V is applied to a high power line VDD. In this case, V_{GS} denotes a gate voltage applied to the thin film transistor, and I_{D}S denotes a magnitude of a current flowing through the thin film transistor.

FIGS. 9A and 9B are transfer curves that may be obtained when thin film transistor substrates according to aspects and comparative examples are turned-on, respectively.

The aspect of FIG. 9A is a thin film transistor substrate according to an exemplary aspect of the present disclosure, and includes an active layer 120 including a first active layer 120a and a third active layer 120c including a crystalline oxide semiconductor, and a second active layer 120b including an amorphous oxide semiconductor.

Unlike the thin film transistor according to the aspect of the present disclosure, the thin film transistor according to the comparative example of FIG. 9B comprises a multilayer active layer including an amorphous oxide semiconductor having high mobility. Specifically, the thin film transistor according to the comparative example includes a high mobility amorphous oxide semiconductor and a relatively low mobility amorphous oxide semiconductor on the upper and lower surfaces of the high mobility amorphous oxide semiconductor.

As shown in FIG. 9B, the mobility of the thin film transistor according to the comparative example is 52.68 cm2/Vs, and the thin film transistor according to the comparative example may be implemented as a device having high mobility.

As shown in FIG. 9A, the mobility of the thin film transistor according to the aspect is 54.99 cm2/Vs, and thus the thin film transistor according to the aspect of the present disclosure may have higher or the same or similar degree of mobility than that of the thin film transistor according to the comparative example. That is, an element having high mobility may be implemented.

As shown in FIG. 9A, according to the aspect of present disclosure, as a result of the process of securing the threshold voltage Vth in the positive (+) direction, the threshold voltage Vth of the thin film transistor according to the aspect may be 0.20 V in the positive (+) direction.

As may be seen from FIG. 9B, as a result of the process of securing the threshold voltage (+) in the positive (+) direction according to the comparative example, the threshold voltage (Vth) of the thin film transistor according to the comparative example may be secured in the positive (+) direction at 0.23 V.

Referring to FIGS. 9A and 9B, the thin film transistor according to an exemplary aspect of the present disclosure and the thin film transistor according to comparative example may ensure similar threshold voltage Vth characteristics and mobility characteristics. However, the reliability of the thin film transistor substrate according to the aspect of present disclosure is improved compared to the thin film transistor substrate according to the comparative example made of amorphous oxide semiconductors, which will be described in detail in FIG. 10 below.

FIG. 10 is a graph on the PBTS (Positive Bias Temperature Stress) test of the thin film transistor substrate according to the aspect of FIG. 9A and the comparative example of FIG. 9B. It is a graph showing a change V of threshold voltage over time (Sec) while applying a constant stress of 30 V and temperature for an hour (1H) to the thin film transistor substrate according to each aspect or comparative example, respectively.

As shown in FIG. 10, the thin film transistor according to the comparative example shows that the change V of the threshold voltage increases at a steep speed at the beginning and then becomes gentle toward the end. However, the change V of the threshold voltage over time (Sec) appears to increase constantly. As a result, it may be confirmed that the PBTS reliability of the thin film transistor according to the comparative example decreases.

On the other hand, the thin film transistor according to the aspect shows that the change V of the threshold voltage gradually increases or remains constant over time (Sec) compared to the comparative example. As a result, it may be seen that the thin film transistor according to the aspect has improved PBTS reliability compared to the thin film transistor according to the comparative example.

As a result, it may be confirmed that the PBTS reliability of the thin film transistor according to the aspect of the present disclosure is superior to the PBTS reliability of the thin film transistor according to the comparative example. That is, the thin film transistor according to the aspect of the present disclosure may be implemented as a device with high mobility, and may be implemented as a device with high reliability even when the process of securing the threshold voltage Vth in the positive (+) direction is performed.

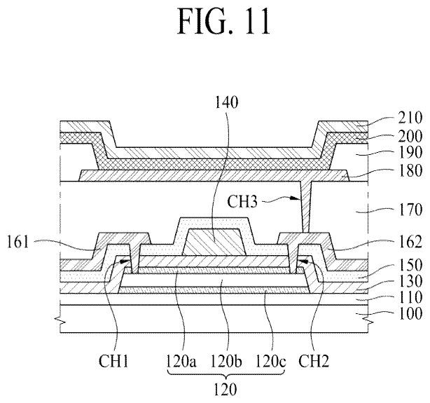

FIG. 11 is a cross-sectional view of a display apparatus including a thin film transistor substrate according to another exemplary aspect of the present disclosure.

As shown in FIG. 11, the display apparatus according to the aspect of present disclosure includes a substrate 100, a buffer layer 110, an active layer 120, a gate insulating film 130, a gate electrode 140, an interlayer insulating film 150, a source electrode 161, a drain electrode 162, a planarization layer 170, a first electrode 180, a bank layer 190, a light emitting layer 200, and a second electrode 210.

Since the substrate 100, buffer layer 110, active layer 120, gate insulating film 130, gate electrode 140, interlayer insulating film 150, source electrode 161, and drain electrode 162 are the same as or similar to the aspects described above, only different configurations will be mainly described below.

The planarization layer 170 is provided on the source electrode 161 and the drain electrode 162. the planarization layer 170 is provided with a third contact hole CH3, so the drain electrode 162 is exposed by the third contact hole CH3. However, in some cases, the source electrode 161 may be exposed by the third contact hole CH3.

the first electrode 180 is formed on the planarization layer 170 and is connected to the source electrode 161 or the drain electrode 162 through the third contact hole CH3. The first electrode 180 may function as an anode.

The bank layer 190 is provided to cover an edge of the first electrode 180 to define a light emitting area. Accordingly, the upper surface area of the first electrode 180 exposed without being covered by the bank layer 190 becomes a light emitting area.

The light emitting layer 200 is provided on the first electrode 180. The light emitting layer 200 may consist of a red, green, and blue emission layer patterned for each pixel, or may consist of a white emission layer connected to all pixels. Aspects are not limited thereto. And pixels of other colors are also possible. When the light emitting layer 200 is made of a white light emitting layer, the light emitting layer 200 may include, for example, a first stack including a blue light emitting layer, a second stack including a yellow green light emitting layer, and a charge generation layer provided between the first stack and the second stack, without being limited thereto.

The second electrode 210 is provided on the light emitting layer 200. The second electrode 210 may function as a cathode.

Although not shown, an encapsulation layer for preventing moisture or oxygen from penetrating may be additionally formed on the second electrode 210.

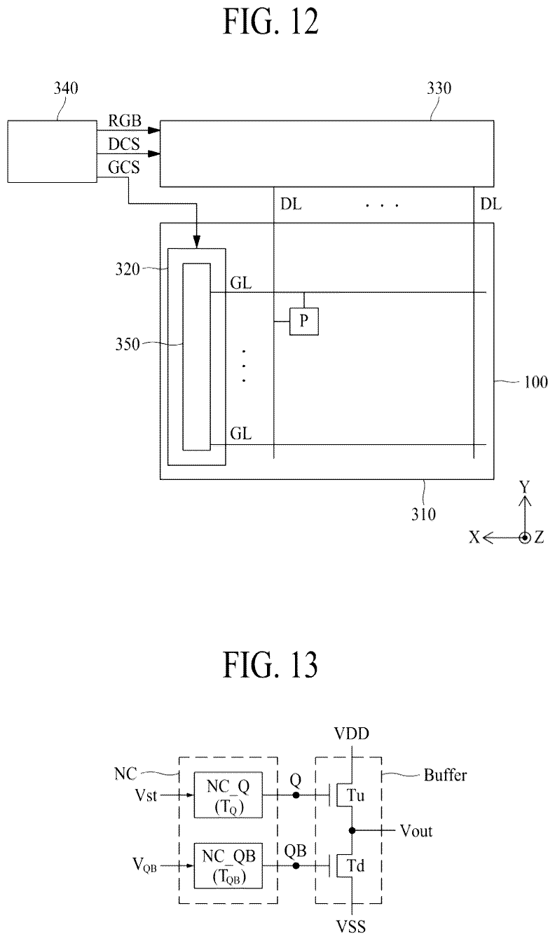

FIG. 12 is a schematic diagram of a display apparatus according to an exemplary aspect of the present disclosure.

As shown in FIG. 12, the display apparatus according to an exemplary aspect of the present disclosure may include a display panel 310, a gate driver 320, a data driver 330, and a controller 340.

The display panel 310 includes gate lines GLs and data lines DLs, and pixels P are disposed in respective crossing areas of the gate lines GLs and data lines DLs. An image is displayed by driving the pixel P. The gate lines GLs, the data lines DLs, and the pixels P may be disposed on the substrate 100.

The controller 340 controls the gate driver 320 and the data driver 330. The controller 340 outputs a gate control signal GCS for controlling the gate driver 320 and a data control signal DCS for controlling the data driver 330 by using a signal supplied from an external system (not shown). Also, the controller 340 samples input video data input from the external system and rearranges the sampled input video data, and supplies the rearranged digital video data RGB to the data driver 330.

The gate control signal GCS includes a gate start pulse GSP, a gate shift clock GSC, a gate output enable signal GOE, a start signal Vst, and a gate clock GCLK. Further, control signals for controlling a shift register may be included in the gate control signal GCS.

The data control signal DCS includes a source start pulse SSP, a source shift clock signal SSC, a source output enable signal SOE, and a polarity control signal POL.

The data driver 330 supplies a data voltage to the data lines DL of the display panel 310. Specifically, the data driver 330 converts the video data RGB inputted from the controller 340 into an analog data voltage and supplies the data voltage to the data lines DL.

The gate driver 320 may be mounted on the display panel 310. As described above, a structure in which the gate driver 320 is directly mounted on the display panel 310 is referred to as a gate in panel (GIP) structure. Specifically, in the gate-in-panel (GIP) structure, the gate driver 320 may be disposed on the substrate 100. Aspects are not limited thereto. As an example, the gate driver 320 may also be connected to the display panel 310 by a chip on film (COF) method, a tape automated bonding (TAB) method or a chip-on-glass (COG) method, etc.

The gate driver 320 may include a shift register 350.

The shift register 350 sequentially supplies gate pulses to the gate lines GL during one frame by the use of start signal and gate clock transmitted from the controller 340. Herein, the one frame refers to a period in which one image is outputted through the display panel 310. The gate pulse has a turn-on voltage capable of turning on a switching device (thin film transistor) disposed in the pixel P.

Also, during the remaining period of one frame, in which the gate pulse is not supplied, the shift register 350 supplies a gate-off signal capable of turning off the switching device to the gate line GL. Hereinafter, the gate pulse and the gate-off signal are totally referred to as a scan signal GS.

FIG. 13 is a circuit diagram of a shift register according to an exemplary aspect of the present disclosure.

As shown in FIG. 13, the GIP circuit includes a pull-up node Q, a pull-down node QB, a node controller NC, and a buffer unit Buffer.

The buffer unit Buffer is connected to an output terminal and includes a pull-up transistor Tu, a pull-down transistor Td, and a capacitor (not shown).

The pull-up transistor Tu is turned on to output the gate-on signal when the pull-up node Q is charged with a gate on voltage. As an example, the gate on voltage could be a gate high voltage or a gate low voltage.

The pull-down transistor Td is turned on to output the gate-off signal when the pull-down node QB is charged with a gate on voltage.

The capacitor C serves to maintain the gate on voltage supplied to the pull-up transistor Tu for one frame, and is provided between the gate terminal and the source terminal of the pull-up transistor Tu.

The node controller NC controls charging and discharging between the pull-up node Q and the pull-down node QB. The node controller NC may include a pull-up node controller NC_Q for controlling charging and discharging of the pull-up node Q and a pull-down node controller NC_QB for controlling charging and discharging of the pull-down node QB. The pull-up node controller NC_Q includes at least one transistor TQ for controlling the pull-up node Q, and the pull-down node controller NC_QB includes at least one transistor TQB for controlling the pull-down node QB.

The output of the gate signal Vout may be stably controlled by the node controller NC. Specifically, as an example, the node controller NC discharges the pull-down node QB to a gate low voltage when the pull-up node Q is charged with a gate high voltage, and discharges the pull-up node Q to a gate low voltage when the pull-down node QB is charged with a gate high voltage.

Therefore, when the start signal Vst is applied, the pull-up node Q is charged with a gate high voltage and the pull-down node QB is discharged with a gate low voltage by the operation of the plurality of transistors TQ and TQB provided in the node controller NC, thereby outputting the high source voltage VDD as the gate signal Vout. In addition, when a discharge signal VQB is applied, the pull-up node Q is charged with a gate low voltage and the pull-down node QB is charged with a gate high voltage by the operation of the plurality of transistors TQ and TQB provided in the node controller NC to output a low power voltage VSS as a gate signal Vout.

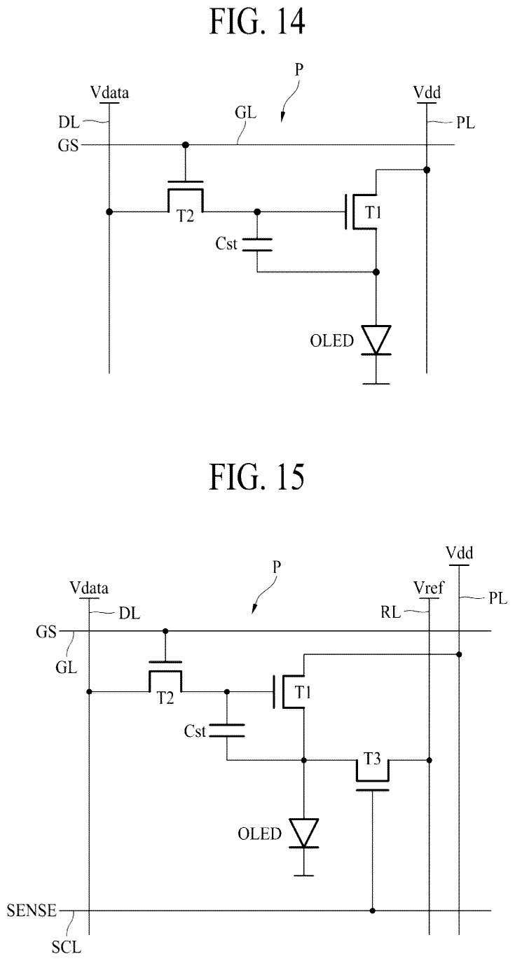

FIG. 14 is a circuit diagram of one pixel provided in a display apparatus according to an exemplary aspect of the present disclosure.

As shown in FIG. 14, the display apparatus according to an exemplary aspect of present disclosure includes first to second thin film transistors T1 and T2 and capacitors Cst.

The first thin film transistor T1 is a driving thin film transistor, and the second thin film transistor T2 is a switching thin film transistor. At least one of the first thin film transistor T1 and the second thin film transistor T2 may be formed of the above-described various thin film transistors.

The first thin film transistor T1 is switched according to the data voltage Vdata supplied from the second thin film transistor T2, generates a data current from the driving voltage Vdd supplied from the power line PL, and supplies it to the organic light emitting diode OLED or other display element such as a light emitting diode LED, a micro LED, etc.

The second thin film transistor T2 is switched according to the scan signal GS supplied to the gate line GL and supplies the data voltage Vdata supplied from the data line DL to the first thin film transistor T1.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

FIG. 15 is a circuit diagram of one pixel provided in a display apparatus according to another exemplary aspect of the present disclosure.

As shown in FIG. 15, the display apparatus according to another exemplary aspect of present disclosure includes first to third thin film transistors T1, T2, T3 and a capacitor Cst.

The first thin film transistor T1 is a driving thin film transistor, and the second to third thin film transistors T2 to T3 are switching thin film transistors. At least one of the first to third thin film transistors T1, T2, and T3 may be formed of the above-described various thin film transistors.

The first thin film transistor T1 is switched according to the data voltage Vdata supplied from the second thin film transistor T2, generates a data current from the driving voltage Vdd supplied from the power line PL, and supplies it to the organic light emitting diode OLED.

The second thin film transistor T2 is switched according to the scan signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

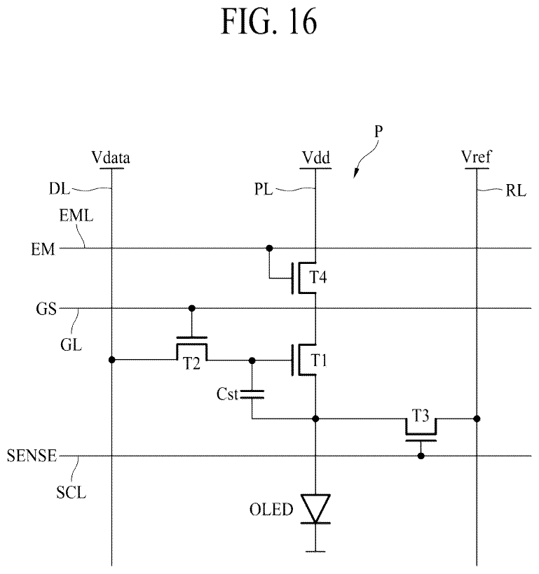

FIG. 16 is a circuit diagram of one pixel provided in a display apparatus according to another exemplary aspect of the present disclosure.

As shown in FIG. 16, the display apparatus according to another exemplary aspect of the present disclosure includes first to fourth thin film transistors T1, T2, T3, and T4 and a capacitor Cst.

The first thin film transistor T1 is a driving thin film transistor, and the second to fourth thin film transistors T2 to T4 are switching thin film transistors. At least one of the first to fourth thin film transistors T1, T2, T3, and T4 may be formed of the above-described various thin film transistors.

The first thin film transistor T1 is switched according to the data voltage Vdata supplied from the second thin film transistor T2, generates a data current from the driving voltage Vdd supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The fourth thin film transistor T4 is switched according to the light emission control signal EM supplied to the light emission control line EML and supplies the driving voltage Vdd supplied from the power line PL to the first thin film transistor T1.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

Accordingly, the present disclosure may have the following advantages.

According to an exemplary aspect of the present disclosure, by forming the second active layer using an oxide semiconductor material having high mobility as amorphous, a main channel is formed in the second active layer to allow a charge carrier to move, thereby realizing a device having high mobility.

According to an exemplary aspect of present disclosure, by providing the first active layer including a crystalline oxide semiconductor between the gate insulating film and the second active layer, it is possible to implement a device with high reliability characteristics that does not degrade reliability even when the process of securing the threshold voltage Vth in a positive (+) direction is carried out.

According to an exemplary aspect of the present disclosure, a first active layer containing an amorphous oxide semiconductor may be provided in a region adjacent to the gate electrode, and a second active layer containing a crystalline oxide semiconductor may be provided in a region less adjacent to the gate electrode. That is, by including the first active layer between the gate electrode and the second active layer, the present disclosure may also be applied to a top gate structure and a bottom gate structure.

According to an exemplary aspect of present disclosure, a first active layer containing crystalline oxide semiconductors in a region adjacent to the first gate electrode, a third active layer containing crystalline oxide semiconductors in a region adjacent to the second gate electrode, and a second active layer containing amorphous oxide semiconductors between the first and third active layers, the present disclosure may be applied to a top gate structure and a bottom gate structure, as well as a double gate structure.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A thin film transistor substrate, comprising:
a substrate;
a gate electrode and an active layer spaced apart in an up and down direction on the substrate, wherein the active layer includes a first active layer and a second active layer, and the first active layer is disposed closer to the gate electrode than the second active layer; and
a gate insulating film disposed between the first active layer and the gate electrode,
wherein the first active layer and the gate insulating film are in contact with each other, and
wherein the first active layer includes a crystalline semiconductor material, and the second active layer includes an amorphous semiconductor material.

2. The thin film transistor substrate according to claim 1, wherein the first active layer includes a crystalline oxide semiconductor material, and the second active layer includes an amorphous oxide semiconductor material.

3. The thin film transistor substrate according to claim 2, wherein a thickness of the first active layer is thinner than that of the second active layer.

4. The thin film transistor substrate according to claim 2, wherein a carrier mobility of the first active layer is lower than that of the second active layer.

5. The thin film transistor substrate according to claim 2, wherein a bandgap energy of the first active layer is greater than a bandgap energy of the second active layer.

6. The thin film transistor substrate according to claim 1, wherein the first active layer includes at least one semiconductor material of a CuO-based oxide semiconductor material, a GaO-based oxide semiconductor material, an InO-based oxide semiconductor material, an InZnO-based oxide semiconductor material, an InGaZnO-based oxide semiconductor material, a SnO-based oxide semiconductor material, and a ZnO-based oxide semiconductor material, and
wherein the second active layer includes at least one semiconductor material of a CuO-based oxide semiconductor material, a GaO-based oxide semiconductor material, an InO-based oxide semiconductor material, an InZnO-based oxide semiconductor material, an InGaZnO-based oxide semiconductor material, a SnO-based oxide semiconductor material, and a ZnO-based oxide semiconductor material.

7. The thin film transistor substrate according to claim 2, wherein a band gap energy of the first active layer is 3.0 eV or more and 3.2 eV or less, and a bandgap energy of the second active layer is 2.6 eV or more and 2.8 eV or less.

8. The thin film transistor substrate according to claim 2, wherein an electrical resistance of the first active layer is greater than that of the second active layer.

9. The thin film transistor substrate according to claim 2, wherein the active layer is disposed under the gate electrode.

10. The thin film transistor substrate according to claim 9, further comprising a source electrode connected to one side of the active layer and a drain electrode connected to another side of the active layer,
wherein at least one of the source electrode and the drain electrode is in contact with the first active layer and is not in contact with the second active layer.

11. The thin film transistor substrate according to claim 9, further comprising a source electrode connected to one side of the active layer and a drain electrode connected to another side of the active layer,
wherein at least one of the source electrode and the drain electrode is in contact with the second active layer.

12. The thin film transistor substrate according to claim 11, wherein the at least one of the source electrode and the drain electrode is in contact with the second active layer through a contact hole provided in the first active layer.

13. The thin film transistor substrate according to claim 2, wherein the active layer is disposed above the gate electrode.

14. The thin film transistor substrate according to claim 2, wherein the active layer further includes a third active layer,
the second active layer is disposed between the first active layer and the third active layer, and
the third active layer includes a crystalline material.

15. The thin film transistor substrate according to claim 14, wherein the first active layer and the third active layer are formed of a same oxide semiconductor material.

16. The thin film transistor substrate according to claim 14, wherein the gate electrode includes a first gate electrode and a second gate electrode,
the first active layer is adjacent to the first gate electrode, and
the third active layer is adjacent to the second gate electrode.

17. The thin film transistor substrate according to claim 16, further comprising a second gate insulating film disposed between the third active layer and the second gate electrode, the third active layer and the second gate insulating film being in contact with each other.

18. The thin film transistor substrate according to claim 16, wherein a thickness of the third active layer is thinner than that of the second active layer.

19. The thin film transistor substrate according to claim 16, wherein a bandgap energy of the third active layer is greater than that of the second active layer.

20. The thin film transistor substrate according to claim 16, wherein an electrical resistance of the third active layer is greater than that of the second active layer.

21. The thin film transistor substrate according to claim 2, wherein a Fermi level of the active layer is closer to a conductive band of the second active layer than to the conductive band of the first active layer.

22. A manufacturing method of a thin film transistor substrate comprising:
forming a second active layer including an amorphous oxide semiconductor material on a substrate;
forming a first active layer including a crystalline oxide semiconductor material on the second active layer;
forming a gate insulating film on the first active layer; and
forming a gate electrode on the gate insulating film.

23. The manufacturing method of claim 22, wherein the forming the second active layer includes forming an IZO-based amorphous oxide semiconductor by a metal organic chemical vaporized deposition MOCVD method or a sputtering method.

24. The manufacturing method of claim 22, wherein the forming the first active layer includes forming the first active layer by a spatiotemporally divided atomic layer deposition (STALD) method.

25. The manufacturing method of claim 22, wherein the forming the first active layer includes forming an IGZO-based crystalline oxide semiconductor including supplying an In source material and an O₂ reactant material, supplying a Ga source material and an O₂ reactant material, and supplying a Zn source material and an O2 reactant material.

26. A manufacturing method of a thin film transistor substrate comprising:
forming a first active layer including a crystalline oxide semiconductor material on a substrate;
forming a second active layer including an amorphous oxide semiconductor material on the first active layer;
forming a gate insulating film on the second active layer; and
forming a gate electrode on the gate insulating film,
wherein the forming the first active layer includes forming an IGZO-based crystalline oxide semiconductor, including supplying an In source material and an O₂ reactant material, supplying a Ga source material and an O₂ reactant material, and supplying a Zn source material and an O₂ reactant material, and
the forming the second active layer includes forming an IZO-based amorphous oxide semiconductor.

27. The manufacturing method of a thin film transistor substrate according to claim 26, wherein the forming the first active layer is performed at a temperature of 300° C. or more and 400° C. or less.

28. A display apparatus comprising:
a thin film transistor substrate according to claim 1.

29. The display apparatus according to claim 28, further comprising:
a display panel including a plurality of gate lines;
a plurality of data lines and a plurality of pixels; and
a gate driver configured to supply scan signals to the plurality of gate lines of the display panel,
wherein each of the plurality of pixels comprises: a display element, a first thin film transistor configured supply a data voltage supplied from the data line to a second thin film transistor according to the scan signal, and the second thin film transistor configured to supply a data current to the display element according to the data voltage, and
wherein the thin film transistor substrate constitutes at least one of the first thin film transistor, the second thin film transistor and a thin film transistor of the gate driver.
